(19) United States
(12) Patent Application Publication
(10) Pub. No.: US 2024/0268183 A1
(43) Pub. Date: Aug. 8, 2024

(54) TOUCH DISPLAY PANELS AND TOUCH DISPLAY DEVICES

(71) Applicant: Shenzhen China Star Optoelectronics Semiconductor Display Technology Co., Ltd., Shenzhen (CN)

(72) Inventor: Chun ZHANG, Shenzhen (CN)

(73) Assignee: Shenzhen China Star Optoelectronics Semiconductor Display Technology Co., Ltd., Shenzhen (CN)

(21) Appl. No.: 18/525,942

(22) Filed: Dec. 1, 2023

(30) Foreign Application Priority Data
Feb. 3, 2023 (CN) 202310148747.0

(51) Int. Cl. H10K 59/40; G06F 3/041; H10K 59/122; H10K 59/80

(52) U.S. Cl. CPC H10K 59/40; G06F 3/0412; H10K 59/122; H10K 59/879; H10K 50/844

(57) ABSTRACT

Touch display panels and touch display devices are provided. The touch display panel includes a display module and a touch module disposed on a light-emitting side of the display module. The touch module includes a first touch metal layer, an interlayer insulating layer, a second touch metal layer, and an organic protective layer disposed on the display module in sequence. The display module includes a plurality of light-emitting areas arranged in an array. The organic protective layer is provided with a plurality of micro-lens structures on a side away from the display module and arranged in one-to-one correspondence with the plurality of light-emitting areas. The micro-lens structure includes at least one convex surface protruding in a direction away from the display module.

### CROSS-REFERENCE TO RELATED APPLICATION

This application claims priority to Chinese patent application No. 202310148747.0, filed on Feb. 3, 2023, the disclosure of which is incorporated herein by reference in its entirety.

### TECHNICAL FIELD

The present disclosure relates to the field of display technologies, and in particular, to touch display panels and touch display devices.

### BACKGROUND

Flexible display technology belongs to the field of flat panel display (FPD) technology and is the general direction for the future development of organic light-emitting diode (OLED) technology. Currently, flexible display products on the market are mainly small and medium-sized products, such as flexible mobile phones, flexible watches, and flexible PADs. However, large-sized flexible TVs (such as active-matrix organic light-emitting diode (AMOLED) TVs) have not yet achieved breakthrough progress. In particular, touch-integrated flexible TVs are still being developed and explored and have not yet been mass-produced.

Thus, how to improve display brightness of the touch-integrated flexible TVs to obtain a better visual experience is an important research direction.

### SUMMARY

In view of above, touch display panels are provided according to embodiments of the present disclosure. The touch display panel includes a display module and a touch module disposed on a light-emitting side of the display module; the touch module includes a first touch metal layer, an interlayer insulating layer, a second touch metal layer, and an organic protective layer disposed on the display module in sequence; the display module includes a plurality of light-emitting areas arranged in an array; the organic protective layer is provided with a plurality of micro-lens structures on a side away from the display module and arranged in one-to-one correspondence with the plurality of light-emitting areas; and the micro-lens structure includes at least one convex surface protruding in a direction away from the display module.

Touch display devices are also provided according to embodiments of the present disclosure. The touch display device includes the above-mentioned display panel.

### BRIEF DESCRIPTION OF THE DRAWINGS

Technical solutions and other beneficial effects of the present disclosure will be apparent through a detailed description of specific embodiments of the present disclosure in conjunction with the accompanying drawings.

FIG. 1 is a partial cross-sectional structural view of a touch display panel provided according to embodiments of the present disclosure.

FIG. 2 is a schematic diagram showing positional relationships between an orthographic projection of a first touch electrode and a second touch electrode on a display module and light-emitting areas of the touch display panel provided according to the embodiments of the present disclosure.

FIG. 3 is a partial cross-sectional view of another touch display panel provided according to embodiments of the present disclosure.

### DETAILED DESCRIPTION

The technical solutions in the embodiments of the present disclosure will be clearly and completely described below with reference to the accompanying drawings. Obviously, the described embodiments are only some of the embodiments of the present disclosure, but not all of the embodiments. Based on the embodiments in the present disclosure, all other embodiments obtained by those skilled in the art without making creative efforts fall within the protection scope of the present disclosure.

In the description of the present disclosure, it needs to be understood that orientations or positional relationships indicated by the terms “center”, “longitudinal”, “transverse”, “length”, “width”, “thickness”, “upper”, “lower”, “front”, “rear”, “left”, “right”, “vertical”, “horizontal”, “top”, “bottom”, “inside”, “outside”, “clockwise”, “counterclockwise” etc. are orientations or positional relationships illustrated in the drawings, which is only for the convenience of describing the present disclosure and simplifying the description, and does not indicate or imply that the device or element referred to must have a specific orientation, be constructed and operated in a specific orientation. Therefore, it cannot be construed as a limitation on the present disclosure.

In addition, the terms “first” and “second” are used for descriptive purposes only and cannot be understood as indicating or implying relative importance or implicitly indicating the quantity of indicated technical features. Thus, features defined as “first” and “second” may explicitly or implicitly include one or more of the described features. In the description of the present disclosure, “plurality” means two or more than two, unless otherwise explicitly and specifically limited.

In the description of the present disclosure, it should be noted that, unless otherwise clearly stated and limited, the terms “arrange”, “communicate”, and “ connect” should be understood in a broad sense. For example, it can be a fixed connection, a detachable connection, or an integrated connection; it can be mechanically connected, electrically connected, or can communicate with each other; it can be a direct connection or an indirect connection through an intermediary; it can be an internal connection between two elements or an interaction between two elements. For those of ordinary skill in the art, the specific meanings of the above terms in the present disclosure can be understood according to specific circumstances.

In the present disclosure, unless otherwise explicitly stated and limited, that a first feature is “above” or “below” a second feature may refer that the first feature is in a direct contact with the second feature, or may refer the first feature is in a non-direct contact with the second feature through additional feature therebetween. Furthermore, that the first feature is “above”, “on”, and “over” a second feature includes the first feature being directly above and diagonally above the second feature, or simply means that the first feature is higher in level than the second feature. That the first feature is “below”, “under”, and “lower” the second feature includes the first feature being directly below and diagonally below the second feature, or simply means that the first feature is less horizontally than the second feature.

The following disclosure provides many different embodiments or examples for implementing the various structures of the present disclosure. To simplify the disclosure of the present disclosure, the components and arrangements of specific examples are described below. Of course, they are merely examples and are not intended to limit the application. Furthermore, the present disclosure may repeat reference numbers and/or reference letters in different examples, such repetition being for the purposes of simplicity and clarity and does not by itself indicate a relationship between the various embodiments and/or arrangements discussed. In addition, the present disclosure provides examples of various specific processes and materials, but one of ordinary skill in the art will recognize the application of other processes and/or the use of other materials.

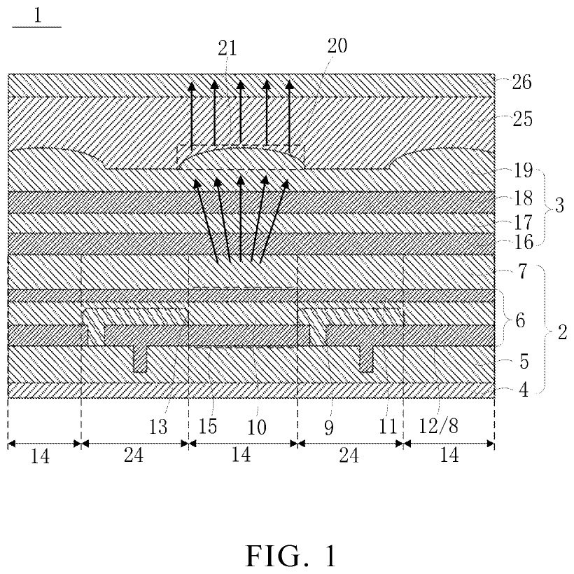

As illustrated in FIG. 1, embodiments of the present disclosure provide a touch display panel 1, which includes a display module 2 and a touch module 3 disposed on a light emitting side of the display module 2.

Specifically, the display module 2 includes a substrate 4 and a driving circuit layer 5, a light-emitting layer 6, and an encapsulation layer 7 which are sequentially arranged on the substrate 4. The touch module 3 is located on the encapsulation layer 7.

Specifically, a material of the substrate 4 includes polyimide (PI), but is not limited thereto. It can be understood that the substrate 4 may be flexible.

Specifically, the driving circuit layer 5 may be a thin film transistor (TFT) array layer, such as an Array layer.

Specifically, the driving circuit layer 5 includes a plurality of driving circuit units (not shown in the figures) and a planarization layer (not shown in the figures) covering the plurality of driving circuit units. Each driving circuit unit includes at least one thin film transistor. The present disclosure does not limit a specific structure of the driving circuit unit.

Specifically, a driving method of the driving circuit layer 5 includes active matrix (AM) driving, but is not limited to this.

Specifically, the light-emitting layer 6 includes a first electrode layer 8, a pixel defining layer 9, an organic light-emitting functional layer 10, and a second electrode layer 11 disposed on the planarization layer in sequence.

Specifically, the first electrode layer 8 includes a plurality of electrode blocks 12 arranged at intervals. The pixel defining layer 9 is located between the plurality of electrode blocks 12 and covers edges of the electrode blocks 12. The pixel defining layer 9 is provided with subpixel openings 13 at positions corresponding to the electrode blocks 12. The organic light-emitting functional layer 10 is at least partially formed in the subpixel openings 13. The second electrode layer 11 covers on an entire surface of the organic light-emitting functional layer 10.

It can be understood that the organic light-emitting functional layer 10 may be entirely provided in the subpixel openings 13, or may have one part provided in the subpixel openings 13 and the other part provided on an entire surface.

Specifically, the plurality of electrode blocks 12 are electrically connected to the plurality of driving circuit units in a one-to-one correspondence.

In a specific embodiment, the first electrode layer 8 is an anode layer, and the second electrode layer 11 is a cathode layer, but is not limited thereto.

Specifically, the display module 2 includes a plurality of light-emitting areas 14 arranged in an array.

In a specific embodiment, each light-emitting area 14 is provided corresponding to one subpixel opening 13.

In another specific embodiment, each light-emitting area is arranged corresponding to three adjacently arranged subpixel openings.

It can be understood that the present disclosure does not limit a size of the light-emitting area. The embodiments of the present disclosure take each light-emitting area corresponding to one subpixel opening as an example for description.

Specifically, the light-emitting layer 6 includes a plurality of organic light-emitting elements 15 arranged in one-to-one correspondence with the plurality of subpixel openings 13 (light-emitting areas 14). It can be understood that each of the organic light-emitting elements 15, such as an OLED element, is formed by a portion of the light-emitting layer 6 corresponding to the subpixel opening 13.

It can be understood that each of the organic light-emitting elements 15 is composed of a portion of the first electrode layer 8, a portion of the organic light-emitting functional layer 10, and a portion of the second electrode layer 11 corresponding to the subpixel opening 13 (light-emitting area 14).

In a specific embodiment, the organic light-emitting element 15 corresponding to the subpixel opening 13 emits any one of red light, green light, and blue light. Of course, in other embodiments, the organic light-emitting element 15 may also emit white light or other specific colors of light.

Specifically, the encapsulation layer 7 is a flexible encapsulation layer, such as a film encapsulation layer. In a specific embodiment, the encapsulation layer 7 includes a first inorganic encapsulation layer, an organic encapsulation layer, and a second inorganic encapsulation layer disposed on the light-emitting layer 6 in sequence. Of course, in other embodiments, the encapsulation layer 7 may only include the organic encapsulation layer.

Specifically, the touch module 3 includes a first touch metal layer 16, an interlayer insulating layer 17, a second touch metal layer 18, and an organic protective layer 19 disposed on the encapsulation layer 7 of the display module 2 in sequence. The organic protective layer 19 is provided with a plurality of micro-lens structures 20 on a side away from the display module 2 and arranged in one-to-one correspondence with the plurality of light-emitting areas 14. Each micro-lens structure 20 includes at least one convex surface 21 protruding in a direction away from the display module 2.

Specifically, the touch module 3 may also include another insulating layer formed on a side of the first touch metal layer 16 away from the interlayer insulating layer 17. A material of the insulating layer and a material of the interlayer insulating layer 17 may be the same or different.

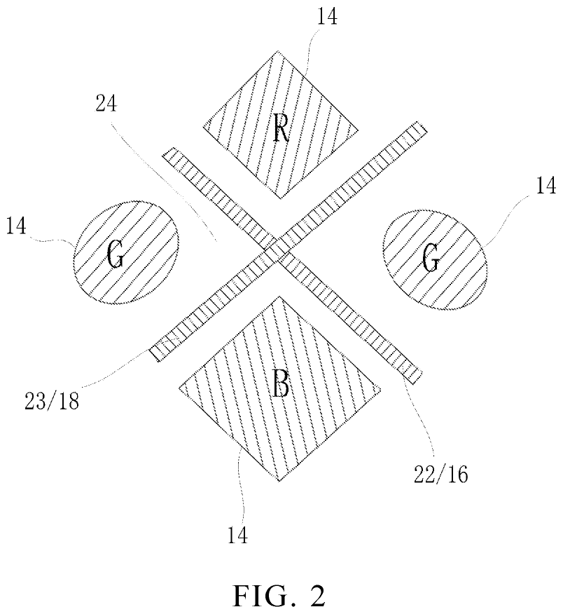

In a specific embodiment, as illustrated in FIG. 2, the first touch metal layer 16 and the second touch metal layer 18 are electrically insulated. The first touch metal layer 16 includes a plurality of first touch electrodes 22, and the second touch metal layer 18 includes a plurality of second touch electrodes 23. Specifically, for the first touch electrode 22 and the second touch electrode 23, one is a touch driving (Tx) electrode, and the other one is a touch driving (Tx) electrode.

In another specific embodiment, the first touch metal layer and the second touch metal layer are electrically connected. The first touch metal layer includes a plurality of bridge portions arranged at intervals, and the second touch metal layer includes a plurality of touch sensing electrodes and a plurality of touch driving electrodes. Specifically, the plurality of touch sensing electrodes and the plurality of touch driving electrodes are intersected and insulated from each other. The plurality of touch sensing electrodes are arranged in multiple rows in a first direction, and each row of touch sensing electrodes extend along a second direction. The plurality of touch drive electrodes are arranged in multiple rows in the second direction, and each row of touch drive electrodes extend along the first direction. The first direction and the second direction are crossed, for example, perpendicular to each other. The touch driving electrodes in each row are directly coupled to each other, and the touch sensing electrodes in each row are coupled in sequence through the plurality of bridge portions. Alternatively, the touch sensing electrodes in each row are coupled to each other, and the touch driving electrodes in each row are coupled in sequence through the plurality of bridge portions.

It should be noted that the present disclosure does not limit the structures of the first touch metal layer 16 and the second touch metal layer 18 of the driving module, and the above are only examples.

Specifically, as illustrated in FIG. 2, the display module 2 also includes a non-light-emitting area 24 located between the plurality of light-emitting areas 14. Orthographic projections of the first touch metal layer 16 and the second touch metal layer 18 on the display module 2 are distributed in the non-light-emitting area 24. It can be understood that orthographic projections of the first touch electrode 22 and the second touch electrode 23 on the display module 2 are distributed in the non-light-emitting area.

In a specific embodiment, the first touch electrode and the second touch electrode each have a mesh structure, and an orthographic projection of each wiring branch constituting the mesh structure on the display module is located in the non-light-emitting area. Of course, the present disclosure does not limit the specific structures of the first touch electrode and the second touch electrode.

Specifically, the organic protective layer 19 is an organic coating (OC) layer, i.e. an insulating film layer made of organic resin, to protect the second touch metal layer 18. Moreover, the organic protective layer 19 is made of a transparent material and does not affect the light emission of the display module 2.

Specifically, the organic protective layer 19 is provided with a plurality of protruding structures on a side away from the display module 2, and at least one protruding structure form the micro-lens structure 20.

In the embodiments of the present disclosure, the micro-lens structure 20 has a light-gathering function, and is specifically configured to gather large-angle light (divergent light or lateral light) emitted from the light-emitting area 14 of the display module 2 toward the middle, that is, the lateral divergent light emitted by the organic light emitting element 15 is converted into parallel light in a direction under the front view, which is beneficial to improving the light extraction efficiency of the display module 2 under the front view, thereby improving the display brightness of the touch display panel 1.

Specifically, a projection of the micro-lens structure 20 in a direction perpendicular to the display module 2 completely covers the corresponding light-emitting area 14, so that the large-angle light emitted by the organic light-emitting element 15 to the surroundings can be concentrated through the corresponding micro-lens structure 20, which is beneficial to improving the light extraction efficiency in a wider range.

In a specific embodiment, each micro-lens structure 20 includes an arc-shaped convex surface 21 protruding away from the display module 2. Specifically, a shape of the convex surface 21 may be semicircular or semielliptical, but is not limited thereto.

In another specific embodiment, each micro-lens structure includes a plurality of arc-shaped convex surfaces distributed in an array and protruding in a direction away from the display module. Specifically, a shape of the convex surface may be semicircular or semielliptical, but is not limited thereto.

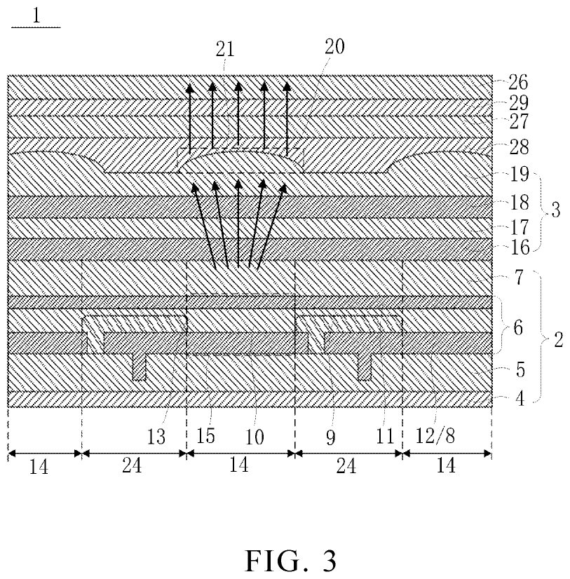

In another specific embodiment, each micro-lens structure may be an irregular convex structure. For example, the convex surface of the micro-lens structure includes at least one inclined surface, and an angle between the inclined surface and an extension direction of the organic protective layer (for example, a horizontal direction illustrated in FIGS. 1 and 3) is an acute angle.

It can be understood that the present disclosure does not limit the shape of the micro-lens structure 20, as long as it has a light-gathering function, and the above embodiments are only examples.

Specifically, when using the organic protective layer 19 in the touch module 3 to make the micro-lens structure 20, the halftone technology (i.e., semi-transparent exposure process) may be used to complete the production in one go. A specific process includes cleaning, coating, exposure, and development.

Specifically, as illustrated in FIG. 1, the touch display panel 1 also includes other functional layers 25 and a protective cover 26 disposed on the organic protective layer 19 in sequence.

In a specific embodiment, as illustrated in FIG. 3, the touch display panel 1 also includes a polarization layer 27 and a protective cover 26 disposed on a side of the touch module 3 away from the display module 2 in sequence. A first adhesive layer 28 is provided between the polarization layer 27 and the organic protective layer 19, and a second adhesive layer 29 is provided between the protective cover 26 and the polarization layer 27. At this time, the other functional layers 25 refer to a laminated structure of the first adhesive layer 28, the polarization layer 27, and the second adhesive layer 29.

In another specific embodiment, the touch display panel further includes a protective cover disposed on the side of the touch module away from the display module, and there is also an adhesive layer between the protective cover and the organic protective layer. At this time, the other functional layers 25 refer to the adhesive layer.

It can be understood that the touch display module 2 mayor may not be provided with the polarization layer. When the polarization layer is not provided, a color filter may be provided on the light-emitting side of the display module to replace the polarization layer and achieve the same function.

Specifically, the protective cover 26 may be a flexible cover for protecting the touch module 3 and the display module 2. The present disclosure does not limit a material of the protective cover 26.

In the embodiments of the present disclosure, the organic protective layer 19 in the touch module 3 is configured to form the micro-lens structures 20 with the light-gathering function. On one hand, there is only need to add steps of exposure and development after forming the organic protective layer 19 when making the micro-lens structure 20, and there is no need to change the entire production process of the touch display panel 1, which is beneficial to saving the production costs of the touch display panel 1 with high light rate. On the other hand, improving the structure of the organic protective layer 19 may not affect the touch effect of the touch module 3 and may also improve the light extraction efficiency of the display module 2. Therefore, the present disclosure may improve the light extraction efficiency of the display module 2 without affecting the touch effect, thereby improving the display brightness of the touch display panel 1 and conducive to obtaining a better visual experience.

Embodiments of the present disclosure also provide touch display devices. The touch display device includes the touch display panel described in the previous embodiments and a housing provided at least on a back side of the touch display panel.

Specifically, a structure of the touch display panel may refer to the description of the foregoing embodiments, and will not be described in detail here. Furthermore, the embodiments of the present disclosure do not limit the structure and material of the housing.

In a specific embodiment, the touch display device is a flexible AMOLED TV.

In the embodiments of the present disclosure, the organic protective layer 19 in the touch module 3 is configured to form the micro-lens structures 20 with the light-gathering function, which may save the production costs and improve the light extraction efficiency of the display module without affecting the touch effect, thereby improving the display brightness of the touch display panel and conducive to obtaining a better visual experience. In the above embodiments, each embodiment is described with its own emphasis. For parts that are not described in detail in a certain embodiment, referring to the relevant descriptions of other embodiments.

The above is detailed introduction to the touch display panels and the touch display devices provided according to the embodiments of the present disclosure. This paper uses specific examples to illustrate the principles and implementation methods of the present disclosure. The description of the above embodiments is only used to help understand the technical solutions and core ideas of the present disclosure. Those of ordinary skill in the art should understand: it is still possible to modify the technical solutions recorded in the foregoing embodiments, or to equivalently replace some of the technical features, and these modifications or substitutions do not cause the essence of the corresponding technical solutions to depart from the scope of the technical solutions of the embodiments of the present disclosure.

What is claimed is:

1. A touch display panel, comprising:
a display module, comprising a plurality of light-emitting areas arranged in an array; and
a touch module, disposed on a light-emitting side of the display module and comprising:
a first touch metal layer, disposed on the display module;
an interlayer insulating layer, disposed on the first touch metal layer;
a second touch metal layer, disposed on the interlayer insulating layer; and
an organic protective layer, disposed on the second touch metal layer, and provided with a plurality of micro-lens structures on a side away from the display module and arranged in one-to-one correspondence with the plurality of light-emitting areas,
wherein each of the micro-lens structures comprises at least one convex surface protruding in a direction away from the display module.

2. The touch display panel according to claim 1, wherein a projection of each of the micro-lens structures in a direction perpendicular to the display module completely covers a corresponding one of the light-emitting areas.

3. The touch display panel according to claim 2, wherein the convex surface is arc-shaped.

4. The touch display panel according to claim 2, wherein the convex surface comprises at least one inclined surface, and an angle between the inclined surface and an extension direction of the organic protective layer is an acute angle.

5. The touch display panel according to claim 1, wherein the plurality of micro-lens structures are parts of the organic protective layer.

6. The touch display panel according to claim 1, wherein a material of the organic protective layer comprises organic resin.

7. The touch display panel according to claim 1, wherein the display module comprises:
a substrate;
a driving circuit layer, disposed on the substrate;
a light-emitting layer, disposed on the driving circuit layer and comprising a plurality of organic light-emitting elements in one-to-one correspondence with the plurality of light-emitting areas; and
an encapsulation layer, disposed on the light-emitting layer,
wherein the touch module is disposed on the encapsulation layer.

8. The touch display panel according to claim 7, wherein the light-emitting layer comprises:
a first electrode layer, disposed on the driving circuit layer;
an organic light-emitting functional layer, disposed on the first electrode layer; and
a second electrode layer, disposed on the organic light-emitting functional layer,
wherein each of the organic light-emitting elements comprises a portion of the first electrode layer, a portion of the organic light-emitting functional layer, and a portion of the second electrode layer.

9. The touch display panel according to claim 8, wherein the first electrode layer comprises a plurality of electrode blocks arranged at intervals, the light-emitting layer further comprises a pixel defining layer disposed between the plurality of electrode blocks and covering edges of the electrode blocks;
the pixel defining layer comprises subpixel openings corresponding to the electrode blocks, the organic light-emitting functional layer is at least partially formed in the subpixel openings, and the light-emitting areas are in in one-to-one correspondence with the subpixel openings.

10. The touch display panel according to claim 1, wherein the touch display panel further comprises:
a polarization layer, disposed on a side of the touch module away from the display module;
a protective cover, disposed on a side of the polarization layer away from the display module;
a first adhesive layer, disposed between the polarization layer and the organic protective layer; and
a second adhesive layer, disposed between the protective cover and the polarization layer.

11. The touch display panel according to claim 1, further comprising:
a protective cover, disposed on a side of the touch module away from the display module; and
an adhesive layer, disposed between the protective cover and the organic protective layer.

12. The touch display panel according to claim 1, wherein projections of the first touch metal layer and the second touch metal layer in a direction perpendicular to the display module are spaced apart from the light-emitting areas.

13. The touch display panel according to claim 1, wherein the first touch metal layer is spaced apart from the second touch metal layer, the first touch metal layer comprises a plurality of first touch electrodes, and the second touch metal layer comprises a plurality of second touch electrodes, orthographic projections of the first touch electrodes and the second touch electrodes on the display module are spaced apart from the light-emitting areas.

14. A touch display device, comprising a touch display panel, and the touch display panel comprising:
a display module, comprising a plurality of light-emitting areas arranged in an array; and
a touch module, disposed on a light-emitting side of the display module and comprising:
a first touch metal layer, disposed on the display module;
an interlayer insulating layer, disposed on the first touch metal layer;
a second touch metal layer, disposed on the interlayer insulating layer; and
an organic protective layer, disposed on the second touch metal layer, and provided with a plurality of micro-lens structures on a side away from the display module and arranged in one-to-one correspondence with the plurality of light-emitting areas,
wherein each of the micro-lens structures comprises at least one convex surface protruding in a direction away from the display module.

15. The touch display device according to claim 14, wherein a projection of each of the micro-lens structures in a direction perpendicular to the display module completely covers a corresponding one of the light-emitting areas.

16. The touch display device according to claim 15, wherein the convex surface is arc-shaped.

17. The touch display device according to claim 15, wherein the convex surface comprises at least one inclined surface, and an angle between the inclined surface and an extension direction of the organic protective layer is an acute angle.

18. The touch display device according to claim 14, wherein the plurality of micro-lens structures are parts of the organic protective layer.

19. The touch display device according to claim 14, wherein a material of the organic protective layer comprises organic resin.

20. The touch display device according to claim 14, wherein the display module comprises:
a substrate;
a driving circuit layer, disposed on the substrate;
a light-emitting layer, disposed on the driving circuit layer and comprising a plurality of organic light-emitting elements in one-to-one correspondence with the plurality of light-emitting areas; and
an encapsulation layer, disposed on the light-emitting layer,
wherein the touch module is disposed on the encapsulation layer.
